(19) United States
(12) Patent Application Publication
(10) Pub. No.: US 2023/0067839 A1
(43) Pub. Date: Mar. 2, 2023

(54) PLASMA ENHANCED THIN FILM DEPOSITION USING LIQUID PRECURSOR INJECTION

(71) Applicants: UNIVERSITY OF SURREY, Guildford, Surrey (GB); Airbus Defence and Space GmbH, Taufkirchen (DE)

(72) Inventors: Ravi Silva, Guildford (GB); Christopher Toby Gibb Smith, Guildford (GB); Jose Anguita, Guildford (GB); Michal Delkowski, Guildford (GB)

(21) Appl. No.: 17/782,196

(22) PCT Filed: Dec. 15, 2020
(86) PCT No.: PCT/GB2020/053225

§ 371 Date: Jun. 3, 2022

(30) Foreign Application Priority Data
Dec. 17, 2019 (GB) 1918651.9

(51) Int. Cl. B05D 1/00

(52) U.S. Cl. CPC B05D 1/60; B05D 2401/33; B05D 2507/005

(57) ABSTRACT

The disclosure provides an apparatus for depositing poly(p-xylylene) onto a component. The apparatus comprises a deposition chamber configured to receive a component to be coated therein; an electrical power supply; a platen, disposed inside the deposition chamber and comprising an electrically conductive material, wherein the platen is electrically connected to the electrical power supply and configured to support the component; a monomer reservoir, configured to receive a monomer of poly(p-xylylene) therein; a monomer conduit extending between the monomer reservoir and the deposition chamber; and a heating means configured to heat the monomer reservoir and the monomer conduit to a temperature of between 25 and 250° C.

The present invention relates to an apparatus for applying a poly(p-xylylene) film to a component. The invention extends to a method of applying the poly(p-xylylene) film to the component.

Poly(p-xylylene) polymer, sold under the trade name Parylene™, is a material that is deposited in thin-film form on a variety of commercial products. The poly(p-xylylene) polymer film is used to seal the products from exposure to an external environment. Accordingly, the film may protect a component from moisture and/or corrosive elements or may make components become biocompatible.

Poly(p-xylylene) polymer deposition takes place inside a vacuum chamber, where the components to be coated are placed. For this, the chamber is evacuated, and a vapour of the poly(p-xylylene) monomer is injected into the chamber. The monomer condenses on the surface of the components where it polymerises, forming the protective parylene coating.

The monomer is typically obtained by vaporising and then cracking a poly(p-xylylene) dimer. The cracking step requires high temperatures. Additionally, the surface area of the solid dimer changes over time leading to unstable vapour flow. This can cause the flow of the monomer into the deposition chamber to vary over time. Furthermore, flow rates will not be reproducible.

It can be difficult to obtain a uniform coating on a component which is large and/or has a complex geometry. Carrier gases, such as argon, can be used to improve uniformity. However, these gases also increase dust formed due to monomers binding to each other prematurely in the vapour phase. Dust particles are often the source of defects, such as pin-holes. Accordingly, it is desirable to avoid dust formation.

The present invention arises from the inventors work in attempting to overcome the problems associated with the prior art.

In accordance with a first aspect, there is provided an apparatus for depositing poly(p-xylylene) onto a component, the apparatus comprising:
a deposition chamber configured to receive a component to be coated therein;
an electrical power supply;
a platen, disposed inside the deposition chamber and comprising an electrically conductive material, wherein the platen is electrically connected to the electrical power supply and configured to support the component;
a monomer reservoir, configured to receive a monomer of poly(p-xylylene) therein;
a monomer conduit extending between the monomer reservoir and the deposition chamber; and
a heating means configured to heat the monomer reservoir and the monomer conduit to a temperature of between 25 and 250° C.

Advantageously, the inventors have found that the above apparatus can be used to produce simple and even three-dimensional components coated with a highly uniform poly(p-xylylene) layer with low impurities.

The monomer may be a solid or a liquid at 20° C. and 101 kPa.

The monomer may be a compound of Formula (I):

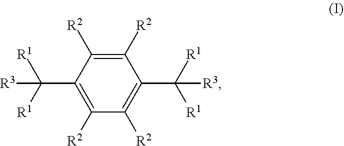

wherein each R¹ is independently H, a C₁₋₅ alkyl, a C₁₋₅ alkoxy, a polymer group chain or a halogen;

each R² is independently H, a C₁₋₅ alkyl, a halogen, CN or C(O)R⁴;

each R³ is OH or a C₁₋₅ alkoxy; and

R⁴ is H, a C₁₋₅ alkyl or a C₁₋₅ alkoxy.

For instance, the monomer may be a compound of formula (Ia), (Ib), I(c) or I(d):

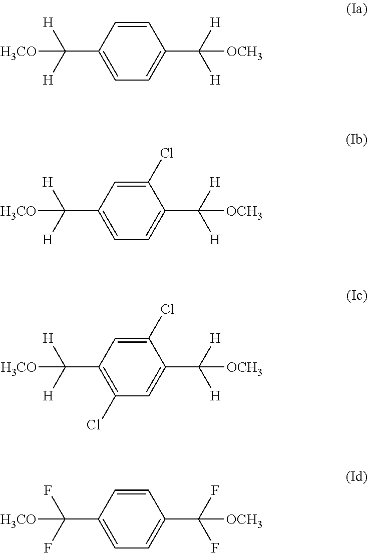 [SMILES: COCc1ccc(COC)cc1 ; COCc1ccc(COC)c(Cl)c1 ; COCc1cc(Cl)c(COC)cc1Cl ; COC(F)(F)c1ccc(C(F)(F)OC)cc1]

However, it may be appreciated that a wide variety of monomers may be used, and the above examples are non-limiting.

The monomer may be configured to produce a poly(p-xylylene) of formula (II):

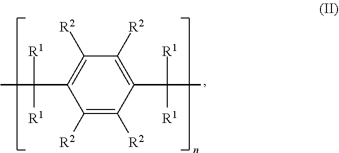

wherein each R¹ and R² are as defined above.

The halogen may be fluorine, chlorine, bromine or iodine, and is preferably fluorine or chlorine.

In a preferred embodiment, each R¹ is independently H or a halogen. The or each halogen may be fluorine.

In a preferred embodiment, each R² is independently H or a halogen. The or each halogen may be fluorine or chlorine.

In a preferred embodiment, each R³ is a C₁₋₅ alkoxy. R³ may be —OCH₃.

The monomer may be configured to produce a poly(p-xylylene) of formula (IIa), (IIb), (IIc) or (IId):

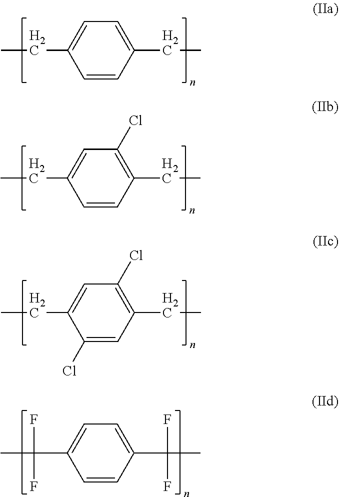

The electrical power supply may be configured to constantly supply electrical power from when it is activated to when it is deactivated. Alternatively, from when it is activated to when it is deactivated, the electrical power supply may be configured to supply electrical power to the platen in a pulsed manner. The inventors have found that supplying electrical power in a pulsed manner increases the uniformity of the poly(p-xylylene) layer.

The inventors believe that this is novel and inventive per se.

Accordingly, in a second aspect, there is provided an apparatus for depositing a coating onto a component, the apparatus comprising:
a deposition chamber configured to receive a component to be coated therein;
an electrical power supply;
a platen, disposed inside the deposition chamber and comprising an electrically conductive material, wherein the platen is electrically connected to the electrical power supply and configured to support the component; and
a feedstock conduit configured to feed a feedstock into the deposition chamber, wherein the feedstock is configured to provide a coating layer on the component,

characterised in that, when activated, the electrical power supply is configured to supply electrical power to the platen in a pulsed manner.

The feedstock may comprise:
a feedstock configured to provide a poly(p-xylylene) layer;
a feedstock configured to provide a diamond-like carbon (DLC) layer;
a feedstock configured to provide a layer comprising a metal or metalloid; and/or
a feedstock configured to provide an inorganic layer.

A metalloid may be understood to be a chemical element with properties that are intermediate between those of metals and nonmetals. For instance, the metalloid may be boron, silicon, germanium, arsenic, antimony, tellurium and polonium, and is preferably silicon.

It may be appreciated that the poly(p-xylylene) layer, DLC layer, layer comprising a metal or metalloid and/or inorganic layer produced using the method could be pure layers consisting entirely of poly(p-xylylene), DLC, a metal or metalloid and/or the inorganic component. Alternatively, it may be appreciated that the layers may be doped layers. Accordingly, the layers could comprise one or more dopants or additives.

In embodiments where the feedstock configured to provide a poly(p-xylylene) layer, it may be appreciated that the apparatus of the second aspect could be used with a monomer of poly(p-xylylene) as defined in relation to the first aspect. Alternatively, or additionally, the apparatus of the second aspect could also be used with a poly(p-xylylene) monomer which has been obtained by decomposing a poly(p-xylylene) dimer.

The poly(p-xylylene) dimer may be a molecule of formula (III):

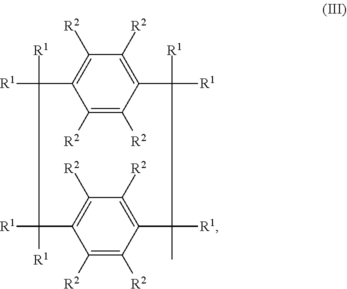

wherein R¹ and R² are as defined above.

The feedstock configured to provide a DLC layer may comprise a carbon source. The carbon source may comprise a C₁ to C₁₅ alkyl, a C₃ to C₁₀ cycloalkyl and/or a C₆ to C₁₀ aryl, wherein the alkyl, cycloalkyl and/or aryl are optionally substituted with a halogen and/or the cycloalkyl and/or aryl are optionally substituted with one or more C₁ to C₁₅ alkyl groups. Preferably, the carbon source comprises a C₁ to C₁₀ alkyl, a C₆ cycloalkyl and/or a C₆ aryl, wherein the alkyl, cycloalkyl and/or aryl are optionally substituted with a halogen and/or the cycloalkyl and/or aryl are optionally substituted with one or more C₁ to C₅ alkyl groups. The halogen is preferably fluorine. Advantageously, the feedstock may produce fluorine doped DLC. The alkyl may be a straight or branched chain alkyl. Accordingly, the carbon source may comprise n-hexane, cyclohexane and/or toluene. Alternatively, the carbon source may comprise a hydrocarbon gas. The hydrocarbon gas may comprise a C₁ to C₅ hydrocarbon. The hydrocarbon gas may comprise methane, ethane, propane, butane, pentane and/or acetylene. The feedstock may comprise the carbon source in an amount which is between 0.01 and 100% (v/v), more preferably between 0.1 and 75% (v/v) or between 1 and 50% (v/v) and most preferably between 5 and 40% (v/v).

The feedstock configured to provide a DLC layer may further comprise a further gas.

The further gas may be a noble gas, nitrogen gas and/or hydrogen gas. The noble gas may comprise helium or argon. The feedstock may comprise the further gas at a concentration between 0 and 99.99% (v/v), more preferably between 25 and 99.9% (v/v) or between 50 and 99% (v/v) and most preferably between 60 and 95% (v/v).

The feedstock configured to provide a DLC layer may further comprise one or more dopants.

The dopant may comprise a metal, preferably a transition metal. Accordingly, the feedstock may comprise a metal, preferably a transition metal. In some embodiments, the feedstock may comprise an organometallic. Advantageously, the organometallic may act as a metal source. The transition metal may be titanium, iron, nickel, cobalt or molybdenum. Advantageously, the metal reduces friction and enhances electrical conductivity. The feedstock may comprise the metal and/or the organometallic at a concentration between 0 and 99.99% (v/v), more preferably between 0.1 and 50% (v/v) or between 0.5 and 25% (v/v) and most preferably between 1 and 5% (v/v).

The dopant may comprise an oxide and/or a nitride, such as silicon oxide (SiOₓ), titanium oxide (TiOₓ) and/or silicon nitride (Si₃N₄). Accordingly, the feedstock may comprise silicon oxide (SiOₓ), titanium oxide (TiOₓ) and/or silicon nitride (Si₃N₄). Advantageously, an oxide or nitride increases heat resistance, minimize friction and increase transparency, scratch resistance and ATOX and/or UV protection. The feedstock may comprise the oxide and/or the nitride at a concentration between 0 and 99.99% (v/v), more preferably between 0.1 and 50% (v/v) or between 0.5 and 25% (v/v) and most preferably between 1 and 5% (v/v).

The dopant may comprise a halogen, oxygen, nitrogen, boron, and/or silicon. Accordingly, the feedstock may comprise a halogen, oxygen, nitrogen, boron, and/or silicon. The feedstock may comprise the halogen, oxygen, nitrogen, boron, and/or silicon at a concentration between 0 and 99.99% (v/v), more preferably between 0.1 and 50% (v/v) or between 0.5 and 25% (v/v) and most preferably between 1 and 5% (v/v).

The feedstock configured to provide a metal or metalloid layer may comprise a metal or metalloid source. The metal source may comprise an organometallic compound. The metal source may be a source of a transition metal or a group 13 metal. The metal source may be a source of tungsten (W), titanium (Ti), niobium (Nb), tantalum (Ta), nickel (Ni), molybdenum (Mo) or aluminium (Al). The metalloid source may comprise boron, silicon, germanium, arsenic, antimony, tellurium or polonium, and preferably comprises silicon.

The feedstock configured to provide the inorganic layer may be conjured to provide a carbide, oxide or nitride. Accordingly, the feedstock configured to provide the inorganic layer may comprise a carbon, oxygen and/or nitrogen source. The feedstock configured to provide the inorganic layer may be conjured to provide a layer comprising a transition metal or p-block metal or metalloid. Accordingly, the feedstock configured to provide the inorganic layer may comprise a transition metal or p-block metal or metalloid source. The transition metal or p-block metal or metalloid may be selected from the group consisting of tungsten (W), titanium (Ti), niobium (Nb), tantalum (Ta), nickel (Ni), molybdenum (Mo), aluminium (Al) or silicon (Si). The feedstock may be configured to provide a layer comprising silicon carbide (SiCₓ), silicon oxide (SiOₓ), silicon oxynitride (SiOₓN_{y}), titanium oxynitride (TiNₓO_{y}), titanium nitride (TiNₓ), titanium oxide (TiOₓ), silicon nitride (SiₓN_{y}) or aluminium oxide (AlₓO_{y}). It may be appreciated that suitable feedstocks will be known by the skilled person. For instance, a feedstock configured to produce a silicon oxide layer may comprise silane (SiH₄) and oxygen.

The apparatus may comprise a feedstock reservoir configured to store the feedstock. The feedstock conduit may extend between the feedstock reservoir and the deposition chamber.

The apparatus may comprise a feedstock valve disposed on the feedstock conduit. The feedstock valve may be configured to selectively isolate the feedstock reservoir from the deposition chamber. The feedstock valve may be a solenoid valve. An electronic controller may be configured to selectively open and close the feedstock valve.

For the avoidance of doubt, the following statements may apply to both the first aspect and the second aspect.

Each pulse may comprise or consist of:
a) a first time period where electrical power is supplied to the platen, and
b) a second time period when electrical power is not supplied to the platen.

It may be appreciated that the length of the pulse, the first time period and the second time period may vary depending upon the size of the deposition chamber, the size of component to be coated, the location of the component within the deposition chamber, the rate that the monomer is fed into the deposition chamber and/or the pressure within the deposition chamber.

In some embodiments, the pulse has a duration of at least 1 second, at least 10 seconds, at least 20 seconds, at least 30 seconds, at least 40 seconds or at least 50 seconds. The pulse may have a duration between 1 second and 1 hour, between 10 seconds and 30 minutes, between 20 seconds and 10 minutes, between 30 seconds and 5 minutes, between 40 seconds and 2 minutes or between 50 seconds and 90 seconds.

The second time period is preferably greater than the first time period. The second time period is preferably at least twice as long as the first time period. More preferably, the second time period is at least 3 times, at least 5 times or at least 10 times as long as the first time period.

The ratio of the first time period to the second time period may be between 1:1 and 1:1,000, more preferably between 1:1.5 and 1:500, between 1:2 and 1:100, between 1:3 and 1:50 or between 1:4 and 1:20, and most preferably is between 1:5 and 1:20 or between 1:10 and 1:12.

The apparatus may comprise an electronic controller.

The electronic controller may be configured to activate the electronic power supply. In embodiments, where the electrical power supply is configured to supply electrical power to the platen in a pulsed manner, the electronic controller may be configured to control the length of the pulses and of the first and second time periods.

The electrical power supply is preferably a direct current (DC) power supply or a radio-frequency electrical power supply. The electrical power supply is more preferably a radio-frequency electrical power supply. Preferably, the radio-frequency electrical power supply operates at a frequency between 0.1 and 100 MHz, more preferably between 1 and 50 MHz or between 5 and 25 MHz, and most preferably at a frequency between 7.5 and 20 MHz or between 10 and 15 MHz. In a preferred embodiment, the radio-frequency electrical power supply operates at a frequency of 13.56 MHz as this is an industrial, scientific and medical (ISM) radio band.

In embodiments where the component comprises an electrically insulating material, the electrical power supply may be configured to apply electrical power to the platen at a power of between 0.0001 Watts/cm² and 10 Watt/cm², more preferably between 0.001 Watts/cm² and 5 Watt/cm² or between 0.005 Watts/cm² and 1 Watts/cm² and most preferably between 0.01 and 0.5 Watts/cm².

In embodiments where the component comprises an electrically conductive material, the electrical power supply may be configured to apply electrical power to an electrically conductive component supported by the platen. Preferably, the electrical power supply is configured to apply electrical power to an electrically conductive component disposed supported by the platen at a power of between 0.0001 Watts/cm² and 10 Watt/cm², more preferably between 0.001 Watts/cm² and 5 Watt/cm² or between 0.005 Watts/cm² and 1 Watts/cm² and most preferably between 0.01 and 0.5 Watts/cm².

The platen may comprise a metal or a conductive composite material. The conductive composite material may comprise a carbon fibre reinforced polymer (CFRP).

The component may comprise an electrically insulating material. The component may consist of an electrically insulating material. The electrically insulating material may comprise a dipole, and more preferably a plurality of dipoles. The, or each, dipole may be an electric dipole. Accordingly, the, or each, dipole may couple to the electrical power supply via the electromagnetic field. The component may comprise a substantially flat surface. The component may have a thickness of less than 25 cm, more preferably less than 10 cm, less than 7.5 cm or less than 5 cm, and most preferably less than 3 cm, less than 2 cm or less than 1 cm. The component may comprise a plastic, a glass, an optically transparent material, a paper, a ceramic and/or an elastomer. The optically transparent material may be a material used for manufacturing lenses for use in the visible, ultraviolet and infrared spectrum, such as germanium (Ge), potassium bromide (KBr) and/or sodium chloride (NaCl). Alternatively, or additionally, the component may comprise a glass-fibre reinforced plastic (GFRP).

In embodiments where the component comprises an electrically insulating material, the platen preferably comprises a plate configured to receive the component thereon. Preferably, the plate is substantially flat. Advantageously, the electric field that the platen generates is able to penetrate through the insulating component thereby creating a plasma. The plasma is driven by the platen and, since the component is disposed between the platen and the plasma, the poly(p-xylylene) monomers/feedstock deposit thereon.

However, in a preferred embodiment, the component comprises an electrically conductive material.

In some embodiments, the component may comprise an electrically insulating material and an electrically conductive material. The electrically conducting material may comprise a mesh disposed within or around the electrically insulating material. Alternatively, the electrically conductive material may define a layer disposed on an outer surface of the electrically insulating material. Alternatively, the component may consist of an electrically conducting material.

Advantageously, the apparatus of the first and second aspects can deposit a coating onto an electrically conductive component with a complex three dimensional shape.

The ionised monomers are attracted to the charged component, deposit thereon and polymerise, creating an even layer of coating, even on complex surfaces. It may be appreciated that any electrically conducting component could be coated using the apparatus of the first or second aspect. Accordingly, the component could comprise a metal, graphite, graphene, carbon nanotubes and/or a conductive composite material. In a preferred embodiment, the component is a carbon fibre reinforced polymer (CFRP).

In embodiments where the component comprises an electrically conductive material, the platen may comprise a plate configured to receive the component thereon. The plate may be as defined above. However, in a preferred embodiment, the platen comprises a resilient clip configured to receive a portion of the electrically conductive component. The resilient clip may comprise a pair of corresponding flanges configured to receive the portion of the electrically conductive component therebetween. Preferably, the portion of the electrically conductive component comprises less than 10% of the surface area of the component, more preferably less than 5%, less than 4% or less than 3% of the surface area of the component, and most preferably less than 2% or less than 1% of the surface area of the component.

Preferably, the apparatus is for use in applying a poly(p-xylylene) film to a component, more preferably for use in applying a poly(p-xylylene) film to an electrically conductive component.

The apparatus preferably comprises an electrode, wherein the electrode is electrically insulated from the platen. In some embodiments, the electrode may be disposed in the deposition chamber. However, in a preferred embodiment, the deposition chamber defines the electrode. Accordingly, the deposition chamber may comprise a conductive material. The conductive material may comprise a metal or a conductive composite material, such as a carbon fibre reinforced polymer (CFRP).

The electrode may be connected to a power supply. However, in a preferred embodiment, the electrode is connected to electrical ground or earth. Accordingly, the electrode may be an earthed electrode. In embodiments where the deposition chamber defines the electrode, the apparatus may comprise an earthed conductive housing.

The apparatus may comprise a vacuum pump. The apparatus may comprise a pump conduit disposed between the vacuum pump and the deposition chamber. The apparatus may comprise a pump valve disposed on the pump conduit, and configured to selectively isolate the vacuum pump from the deposition chamber. The pump valve may be a solenoid valve, a gate valve or a throttle valve. The gate valve may be a manual gate valve or a pneumatic gate valve. The throttle valve may be an automatic pressure controller (APC) valve. An APC valve can automatically set its position in order to adjust a set pressure (ascertained from a pressure gauge in the main chamber) via electronics. The electronic controller may be configured to selectively open and close the pump valve.

Preferably, the vacuum pump is configured to reduce the pressure of the deposition chamber to a pressure of less than 10 Torr, less than 1 Torr or less than 0.1 Torr, more preferably less than 50 mTorr, less than 40 mTorr, less than 30 mTorr, less than 20 mTorr or less than 10 mTorr, and most preferably less than 5 mTorr or less than 1 mTorr.

In embodiments where the apparatus comprises a heating means, the heating means may comprise a heater. The heating means may comprise a jacket heater and/or a trace heater. In a preferred embodiment, the heating means comprises a jacket heater and a trace heater.

The heating means may comprise a first heater configured to heat the monomer reservoir and a second heater configured to heat the monomer conduit. In some embodiments, the first heater comprises a jacket heater disposed adjacent to the monomer reservoir. In some embodiments, the second heater comprises a trace heater disposed adjacent to the monomer conduit.

It may be appreciated that the temperature the heating means is configured to heat the monomer reservoir and monomer conduits to may vary depending upon the boiling point of the monomer.

The heating means may be configured to heat the monomer reservoir to a temperature of at least 30° C., more preferably at least 40° C. or at least 45° C., and most preferably at least 50° C. The heating means may be configured to heat the monomer reservoir to a temperature of between 30 and 200° C., to a temperature of between 40 and 150° C. or between 50 and 125° C., and most preferably between 50 and 100° C.

The heating means may be configured to heat the monomer conduit to a temperature higher than the monomer reservoir. Advantageously, this temperature gradient prevents condensation of the monomer within the monomer conduit.

The heating means may be configured to heat the monomer conduit to a temperature at least 1° C. higher than the temperature of the monomer reservoir, more preferably at least 2.5° C., at least 5° C. or at least 7.5° C. higher than the temperature of the monomer reservoir and most preferably at least 9° C. higher than the temperature of the monomer reservoir. The heating means may be configured to heat the monomer conduit to a temperature between 1 and 100° C. higher than the temperature of the monomer reservoir, more preferably between 2.5 and 50° C., between 5 and 25° C. or between 7.5 and 15° C. higher than the temperature of the monomer reservoir and most preferably between 9 and 11° C. higher than the temperature of the monomer reservoir.

The heating means may be configured to heat the monomer conduit to a temperature of at least 40° C., more preferably at least 50° C. or at least 55° C., and most preferably at least 60° C. The heating means may be configured to heat the monomer conduit to a temperature of between 40 and 210° C., to a temperature of between 50 and 160° C. or between 60 and 135° C., and most preferably between 60 and 110° C.

The apparatus may comprise a plurality of monomer conduits. The heating means may be configured to heat each of the plurality of monomer conduits as explained above. For example, the heating means may comprise a plurality of second heaters, such that there is a second heater associated with each monomer conduit. The plurality of monomer conduits may extend between a single monomer reservoir and the deposition chamber. Alternatively, the plurality of monomer conduits may extend between a plurality of monomer reservoirs and the deposition chamber. The heating means may be configured to heat each of the plurality of monomer reservoirs as explained above. For example, the heating means may comprise a plurality of first heaters, such that there is a first heater associated with each monomer reservoir. Preferably, the plurality of monomer conduits are configured to inject the monomer into the deposition chamber at a plurality of locations. Preferably, the plurality of locations are spaced apart.

Advantageously, injecting the monomer into the deposition chamber at a plurality of locations increases the uniformity of concentration of the monomer within the deposition chamber. This in turn will increase the uniformity of the poly(p-xylylene) layer on the component.

The plurality of monomer conduits may comprise at least 2, at least 3 or at least 4 conduits. The plurality of monomer conduits may comprise between 2 and 20 conduits, between 3 and 10 conduits or between 4 and 5 conduits. It may be appreciated that the number of conduits may be selected based upon the size of the deposition chamber.

The plurality of monomer reservoirs may comprise at least 2, at least 3 or at least 4 conduits. The plurality of monomer reservoirs may comprise between 2 and 20 conduits, between 3 and 10 conduits or between 4 and 5 conduits.

The electronic controller may be configured to activate and deactivate the heating means.

The heating means may be configured to heat each monomer reservoir and each monomer conduit. The heating means may comprise a plurality of heaters. The electronic controller may be configured to selectively activate and deactivate specific heaters within the plurality of heaters. Accordingly, the electronic controller may be configured to cause the heating means to selectively heat specific monomer reservoirs and monomer conduits within the plurality of monomer reservoirs and monomer conduits.

The apparatus may comprise a mass flow controller disposed on the monomer conduit and configured to control the flow rate of the monomer into the deposition chamber. In embodiments where the apparatus comprises a plurality of monomer conduits, the apparatus may comprise a plurality of mass flow controller, with at least one mass flow controller disposed on each monomer conduit. The electronic controller may be configured to control the flow rate through the or each mass flow controller. The or each mass flow controller may be a liquid mass flow controller.

It may be appreciated that the flow rate of the monomer may depend upon a number of factors including the size of the deposition chamber and the number of injection points. In some embodiments, the electronic controller may be configured to control the flow rate through the or each mass flow controller to a rate of between 0.01 and 100 sccm, between 0.1 and 50 sccm or between 1 and 25 sccm.

The apparatus may comprise a monomer valve disposed on the monomer conduit and configured to selectively isolate the monomer reservoir from the deposition chamber. In embodiments where the apparatus comprises a plurality of monomer conduits, the apparatus may comprise a plurality of monomer valves, with at least one monomer valve disposed on each monomer conduit. The, or each, monomer valve may be a solenoid valve. The electronic controller may be configured to selectively open and close the, or each, monomer valve.

The apparatus may comprise an injector, configured to inject an additive and/or a carrier gas into the deposition chamber. The injector may comprise a store, configured to store an additive and/or a carrier gas, and a further conduit extending between the store and the deposition chamber. A further valve may be disposed on the further conduit configured to selectively isolate the store from the deposition chamber. The injector may further comprise a pump configured to pump the additive and/or carrier gas from the store, along the further conduit and into the deposition chamber. The valve may comprise a solenoid valve. The electronic controller may be configured to open and close the further valve. The additive may be a liquid or a gas. The additive or carrier gas may be hydrogen, nitrogen, a hydrocarbon, an alkylamide, an organometallic compound and/or a noble gas. The hydrocarbon may be acetylene. The organometallic compound may be a metal P-diketonate, a metal cyclopentadienyl, a metal alkoxide or a metal alkylamide. The organometallic compound may be titanium isopropoxide (TIPP). Alternatively, the organometallic compound may be a precursor of silicon, such as silane or tetraethyl orthosilicate (TEOS). The noble gas may be argon. In some embodiments, hydrogen is used as a carrier gas.

The carrier gas may be supplied at a flow rate of between 1 and 50 sccm, more preferably between 3 and 40 sccm, between 4 and 30 sccm or between 5 and 20 sccm, and most preferably between 7 and 15 sccm or between 8 and 12 sccm. Advantageously, the inventors have found that a carrier gas improves the uniformity of deposition.

The apparatus may comprise a pressure sensor. The pressure sensor may be disposed in the deposition chamber. The electronic controller may be configured to monitor the pressure in the deposition chamber.

The electronic controller may be configured to initiate a coating cycle when it receives an input from a user.

The electronic controller may be configured to determine whether the deposition chamber is hermetically sealed prior to initiating a coating cycle. The electronic controller may be configured to initiate a coating cycle after determining that the deposition chamber is hermetically sealed.

The electronic controller may be configured to initiate a coating cycle by being configured to activate the vacuum pump. If the pump valve is closed when the electronic controller receives an input from a user to initiate a coating cycle, the electronic controller may be configured to open the pump valve at the same time or prior to activating the vacuum pump.

The electronic controller may be configured to initiate a coating cycle by being configured to activate the heater when the pressure in the deposition chamber has fallen below a predetermined pressure. The predetermined pressure may be a pressure of less than 10 Torr, less than 1 Torr or less than 0.1 Torr, more preferably less than 50 mTorr, less than 40 mTorr, less than 30 mTorr, less than 20 mTorr or less than 10 mTorr, and most preferably less than 5 mTorr or less than 1 mTorr.

In embodiments where the apparatus is configured to run multiple coating cycles, the electronic controller may be configured to activate the heater when initiating a first coating cycle.

The electronic controller may be configured to activate the heater by being configured to activate at least one heating element such that at least one monomer reservoir and corresponding monomer conduit are heated.

The electronic controller may be configured to initiate a coating cycle by being configured to open the, or each, monomer valve. In embodiments where a select number of heating elements are activated to heat a select number of monomer reservoirs and corresponding monomer conduits, the electronic controller may be configured to initiate a coating cycle by opening the monomer valves in only the monomer conduits where the corresponding heating element is selected to be activated. The electronic controller may be configured to open the, or each, monomer valve prior to or at the same time as activating the heater.

The electronic controller may be configured to initiate a coating cycle by being configured to activate the electrical power supply, after having activated the heater and when the pressure in the deposition chamber has risen above a predetermined pressure. The predetermined pressure may be a pressure of at least 1 mTorr, more preferably at least 10 mTorr, at least 20 mTorr, at least 30 mTorr, at least 40 mTorr or at least 50 mTorr, and most preferably at least 0.1 Torr, at least 1 Torr or at least 10 Torr.

The electronic controller may be configured to activate and deactivate the injector, and thereby selectively inject a gas into the deposition chamber. The electronic controller may be configured to activate and deactivate the injector at any point in the coating cycle depending upon the desired functionality of the coating.

The apparatus may comprise a temperature sensor disposed in the, or each, monomer reservoir and/or in the, or each, monomer conduit. The electronic controller may be configured to monitor the temperature in the, or each, monomer reservoir and/or in the, or each, monomer conduit after the heater has been activated. The electronic controller may be configured to maintain the temperature in the, or each, monomer reservoirs and/or the, or each, monomer conduits within a predetermined range after the heater has been activated. In embodiments where a select number of heating elements are activated to heat a select number of monomer reservoirs and corresponding monomer conduits, the electronic controller may be configured to maintain the temperature in the, or each, select monomer reservoirs and/or monomer conduits where the corresponding heating element has been activated.

The apparatus may comprise a monitor configured to monitor the thickness of a layer deposited on the component during a coating cycle. The monitor may comprise a crystal film thickness monitor.

The electronic controller may be configured to finish a coating cycle (a) a predetermined time after the electrical power supply was activated, (b) when a coating layer with a desired thickness has been deposited on the component, and/or (c) when it receives an input from a user.

The electronic controller may be configured to control the apparatus to deposit additional layers coating the component. The additional layers may comprise a different material to the preceding layer.

Alternatively or additionally, the electronic controller may be configured to power down the apparatus. The electronic controller may power down the apparatus after a predetermined number of coating cycles have been run and/or when it receives an input from a user. The electronic controller may power down the apparatus instead of finishing a coating cycle. Accordingly, the electronic controller may power down the apparatus (a) a predetermined time after the electrical power supply was activated, (b) when a coating layer with a desired thickness has been deposited on the component, and/or (c) due to an input from a user.

It may be appreciated that the predetermined time may vary depending upon a number of facts including the geometry of the component being coated and the desired thickness of the coating layer. Accordingly, it may be appreciated that the predetermined time may be determined by the skilled person. In one embodiment, the predetermined time may be at least 5 minutes, more preferably at least 30 minutes, at least 1 hour or at least 1.5 hours, and most preferably at least 2 hours. In one embodiment, the predetermined time may be less than 12 hours, more preferably less than 6 hours, less than 5 hours or less than 4 hours, and most preferably less than 3 hours. In one embodiment, the predetermined time may be between 5 minutes and 12 hours, more preferably between 30 minutes and 6 hours, between 1 hour and 5 hours or between 1.5 hours and 4 hours, and most preferably between 2 and 3 hours.

It may be appreciated that the desired thickness of the coating layer may vary depending upon the component. If the component comprises a smooth surface, the coating layer may be at least 50 nm. Accordingly, in some embodiments, a coating layer of between 50 nm and 1 μm may be applied. In some embodiments, a thicker coating layer may be desirable. Accordingly, the deposition layer may be at least 1 μm, and may be between 50 μm and 100 μm. Alternatively, if the component comprises a rough surface, then it may be desirable for the thickness of the coating layer to be thicker than the depth of the roughness of the surface of the component. In alternative embodiments, the coating layer may be less than 50 nm.

The electronic controller may be configured to finish a coating cycle and/or power down the apparatus by closing the, or each, monomer valve.

The electronic controller may be configured to finish a coating cycle and/or power down the apparatus by deactivating the electrical power supply. The electronic controller may be configured to deactivate the electrical power supply prior to, at the same to as or after closing the, or each, monomer valve.

The electronic controller may be configured to finish a coating cycle and/or power down the apparatus by venting the apparatus. The electronic controller may be configured to vent the apparatus after it has deactivated the power supply and closed the, or each, monomer valve. Preferably, venting the apparatus comprises raising the pressure in the deposition chamber to about atmospheric pressure. Advantageously, a user can then remove the component from the deposition chamber and place a further to be coated component therein.

In embodiments where the injector is activated, the electronic controller may be configured to finish a coating cycle and/or power down the apparatus by deactivating the injector. The electronic controller may be configured to deactivate the injector by closing the gas valve. The electronic controller may be configured to deactivate the injector prior to venting the apparatus. The electronic controller may be configured to deactivate the injector prior to, at the same time as or after deactivating the electrical power and/or closing the, or each, monomer valve.

The electronic controller may be configured to power down the apparatus by deactivating the heater. The electronic controller may be configured to deactivate the heater prior to, at the same time as or after deactivating the electrical power and/or closing the, or each, monomer valve. Conversely, the electronic controller may be configured to leave the heater activated when finishing a coating cycle. Advantageously, this means that at least a portion of the monomer will already be vaporised when the next coating cycle starts, reducing the time required for subsequent cycle to initiate.

The inventors believe that their methods of depositing a coating layer on a component are also novel and inventive.

Accordingly, in accordance with a third aspect, there is provided a method of depositing a poly(p-xylylene) layer onto a component, the method comprising:
supporting the component on a platen within a deposition chamber, wherein the platen comprises an electrically conductive material and is connected to an electrical power supply;
heating a monomer of poly(p-xylylene) to a temperature of between 25 and 250° C., and thereby causing it to vaporise, and feeding the monomer along a monomer conduit to the deposition chamber, wherein the monomer conduit is heated to a temperature of between 25 and 250° C.;
activating the electrical power supply and thereby creating a plasma that surrounds the component and ionises and/or activates the monomer of poly(p-xylylene); and
allowing the ionised and/or activated monomer of poly(p-xylylene) to deposit on the component and polymerise, and thereby form poly(p-xylylene) on the component.

The monomer of poly(p-xylylene) may be as defined in relation to the first aspect.

The method may comprise causing the electrical power supply to provide electrical power to the platen in a pulsed manner. Accordingly, the plasma will only be present when the electrical power is supplied to the platen. When electrical power is not supplied to the platen, the plasma will be absent.

In embodiments where the component comprises an electrically insulating material it may be appreciated that the monomer of poly(p-xylylene) may only deposit on one side thereof. Accordingly, subsequent to the steps recited above, the method may further comprise:
repositioning the component on platen to expose an uncoated side thereof;
feeding the monomer of poly(p-xylylene) to the deposition chamber; and
allowing the ionised and/or activated monomer of poly(p-xylylene) to deposit on the uncoated side of the component and polymerise, and thereby form poly(p-xylylene) on the component.

In accordance with a fourth aspect, there is provided a method of depositing a coating onto a component, the method comprising:
supporting the component on a platen within a deposition chamber, wherein the platen comprises an electrically conductive material and is connected to an electrical power supply;
feeding a feedstock into the deposition chamber, wherein the feedstock is configured to provide a coating layer on the component;
activating the electrical power supply, and causing it to provide electrical power to the platen in a pulsed manner, such that when electrical power is supplied to the platen a plasma is created that surrounds the component and ionises and/or activates particles within the feedstock; and
allowing the ionised and/or activated particles to deposit on the component and polymerise, and thereby form a coating on the component.

The feedstock may be as defined in relation to the second aspect.

In embodiments where the component comprises an electrically insulating material it may be appreciated that the feedstock may only form a coating on one side thereof.

Accordingly, subsequent to the steps recited above, the method may further comprise:
repositioning the component on platen to expose an uncoated side thereof;
feeding the feedstock into the deposition chamber; and
allowing the ionised and/or activated monomer of particles to deposit on the uncoated side of the component and polymerise, and thereby form a coating on the component.

For the avoidance of doubt, the following statements may apply to both the third or fourth aspects.

The component, deposition chamber and electrical power supply may be as defined in relation to the first and second aspects. The electrical power supply may also be pulsed as defined in relation to first and second aspects.

Preferably, the method is a method of depositing a poly(p-xylylene) film on the component.

The method may comprise heating a monomer reservoir comprising the monomer of poly(p-xylylene), and thereby causing the monomer it to vaporise. The method may comprise heating the monomer reservoir to a temperature of at least 30° C., more preferably at least 40° C. or at least 45° C., and most preferably at least 50° C. The method may comprise heating the monomer reservoir to a temperature of between 30 and 200° C., to a temperature of between 40 and 150° C. or between 50 and 125° C., and most preferably between 50 and 100° C.

The method may comprise heating the monomer conduit to a temperature higher than the monomer reservoir. The method may comprise heating the monomer conduit to a temperature at least 1° C. higher than the temperature of the monomer reservoir, more preferably at least 2.5° C., at least 5° C. or at least 7.5° C. higher than the temperature of the monomer reservoir and most preferably at least 9° C. higher than the temperature of the monomer reservoir. The method may comprise heating the monomer conduit to a temperature between 1 and 100° C. higher than the temperature of the monomer reservoir, more preferably between 2.5 and 50° C., between 5 and 25° C. or between 7.5 and 15° C. higher than the temperature of the monomer reservoir and most preferably between 9 and 11° C. higher than the temperature of the monomer reservoir.

The method may comprise heating the monomer conduit to a temperature of at least 40° C., more preferably at least 50° C. or at least 55° C., and most preferably at least 60° C. The method may comprise heating the monomer conduit to a temperature of between 40 and 210° C., to a temperature of between 50 and 160° C. or between 60 and 135° C., and most preferably between 60 and 110° C.

The method may comprise controlling the flow rate of the monomer along the monomer conduit. The flow rate may be controlled using a mass flow controller. The flow rate may be as defined in relation to the first and second aspects.

Prior to feeding the monomer of poly(p-xylylene) into the deposition chamber, the method may comprise reducing the pressure in the deposition chamber. The method may comprise reducing the pressure to less than 10 Torr, less than 1 mTorr or less than 0.1 mTorr, more preferably less than 50 mTorr, less than 40 mTorr, less than 30 mTorr, less than 20 mTorr or less than 10 mTorr, and most preferably less than 5 mTorr or less than 1 mTorr.

Feeding the monomer of poly(p-xylylene) into the deposition chamber may cause the pressure in the deposition chamber to rise. The method may comprise monitoring the pressure in the deposition chamber while feeding the monomer of poly(p-xylylene) therein, and activating the electrical power supply after the pressure reaches a predetermined pressure. The predetermined pressure may be a pressure of at least 1 mTorr, more preferably at least 10 mTorr, at least 20 mTorr, at least 30 mTorr, at least mTorr or at least 50 mTorr, and most preferably at least 0.1 Torr, at least 1 Torr or at least 10 Torr.

Activating the electrical power supply may comprise applying an electrical power to the electrically conductive component and/or the platen of between 0.0001 Watts/cm² and Watt/cm², more preferably between 0.001 Watts/cm² and 5 Watt/cm² or between 0.005 Watts/cm² and 1 Watts/cm² and most preferably between 0.01 and 0.5 Watts/cm².

The method may comprise feeding an additive into the deposition chamber. The additive may be as defined in relation to the first and second aspects. In one embodiment, the method comprises feeding the additive into the deposition chamber for the entire time that the electrical power supply is activated. In an alternative embodiment, the method comprises feeding the additive into the chamber for discrete intervals while the electrical power supply is activated.

The electrical power supply may have remained active throughout the above steps. Alternatively, if the electrical power supply is deactivated prior to repositioning the component, the method may comprise activating the electrical power supply after the component has been repositioned.

The method may comprise deactivating the electrical power supply. The electrical power supply may be deactivated a predetermined time after it has been activated or when a layer deposited on the component has reached a desired thickness.

The method may comprise venting the deposition chamber. The deposition chamber may be vented after the electrical power supply has been deactivated. Venting the deposition chamber may comprise raising the pressure therein to atmospheric pressure.

The method may comprise closing a monomer valve to isolate a monomer reservoir. The monomer valve may be closed prior to, at the same time as or after the electrical power supply is deactivated. The monomer valve may be closed before the deposition chamber is vented.

All features described herein (including any accompanying claims, abstract and drawings), and/or all of the steps of any method or process so disclosed, may be combined with any of the above aspects in any combination, except combinations where at least some of such features and/or steps are mutually exclusive.

For a better understanding of the invention, and to show how embodiments of the same may be carried into effect, reference will now be made, by way of example, to the accompanying drawings, in which:—

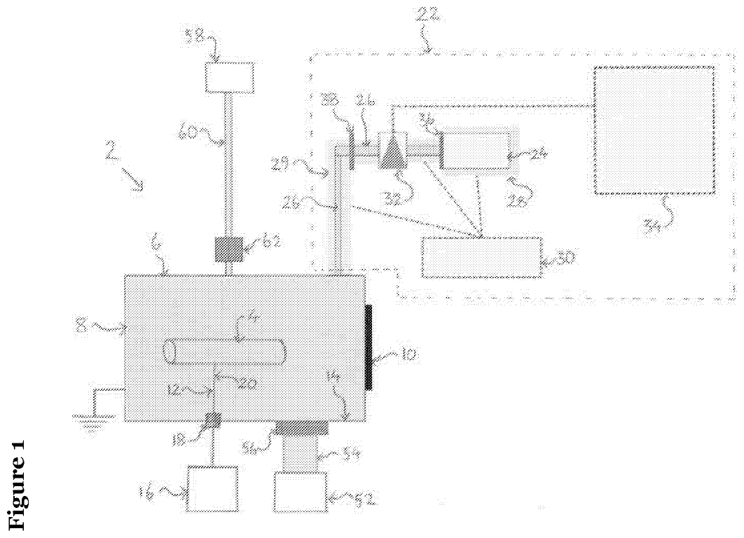

FIG. 1 is a schematic diagram of an apparatus for depositing a film of poly(p-xylylene) polymer on a component;

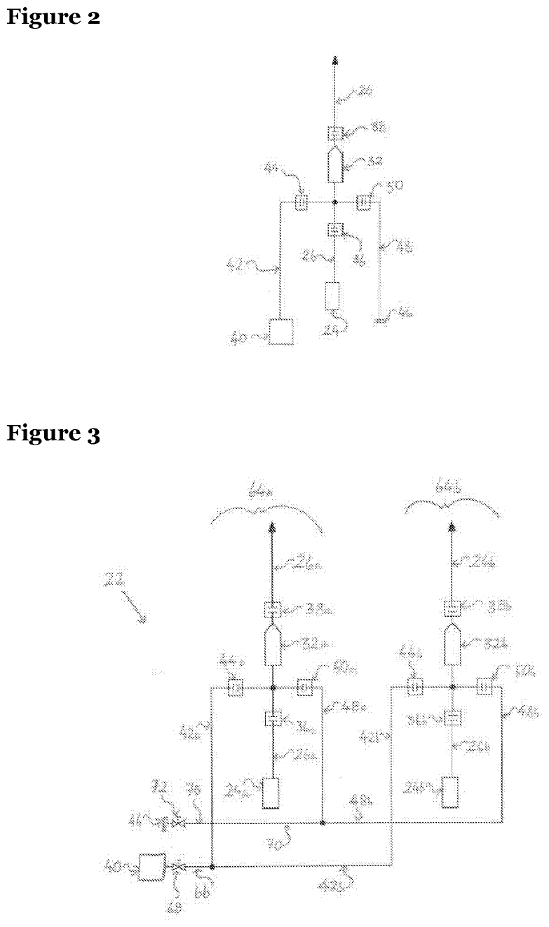

FIG. 2 is a schematic diagram of a feedstock delivery apparatus;

FIG. 3 is a schematic diagram of an alternative feedstock delivery apparatus;

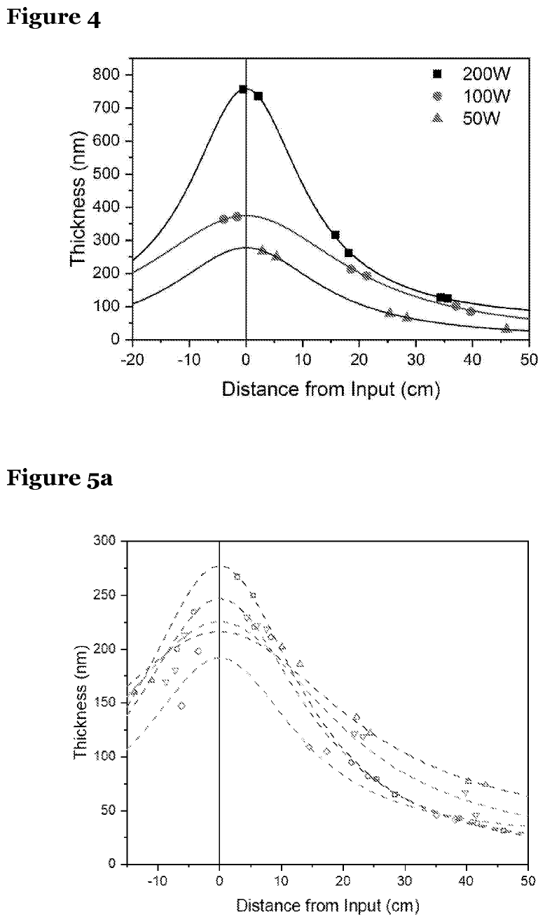

FIG. 4 is a graph showing the distance a component was placed from the input of the monomer and thickness of the deposited layers when different power levels were used;

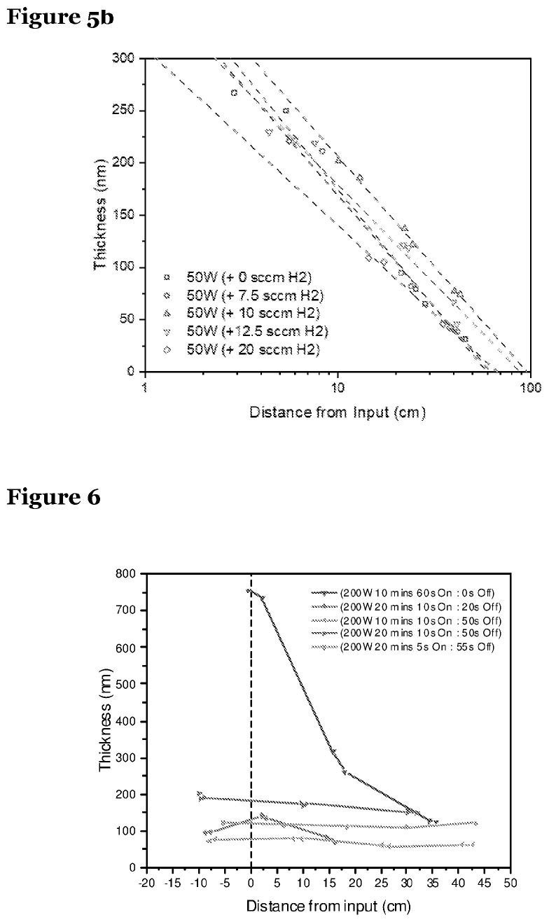

FIGS. 5a and 5b are graphs showing the distance a component was placed from the input of the monomer and thickness of the deposited layers when a power level of 50 W was used and different amounts of hydrogen gas was present;

FIG. 6 is a graph showing the distance a component was placed from the input of the feedstock and thickness of the deposited layers when a power level of 200 W was used and the radio-frequency power supply was either on constantly or was pulsed;

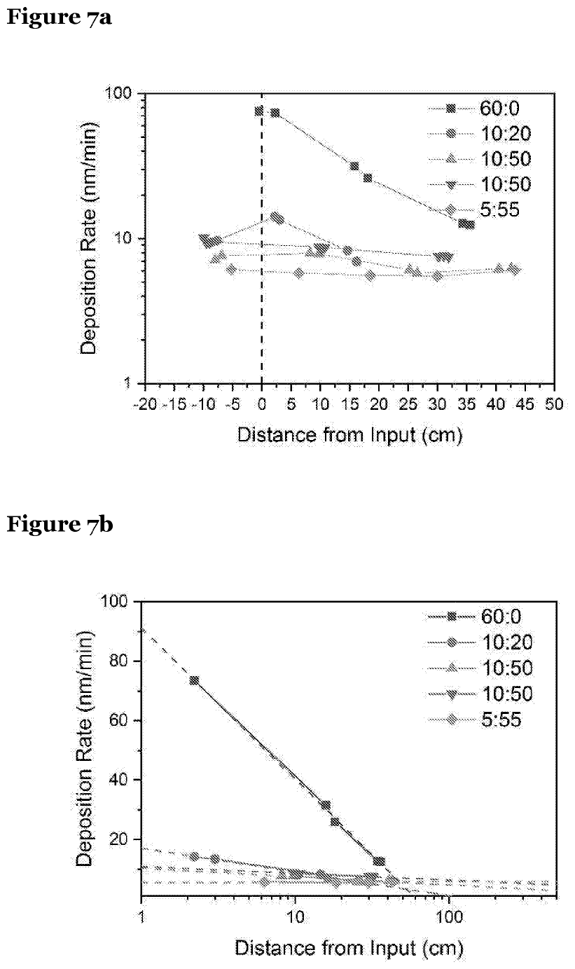

FIGS. 7a and 7b are graphs showing the distance a component was placed from the input of the feedstock and the average deposition rate of the deposited layers across the length of the deposition process when a power level of 200 W was used and the radio-frequency power supply was either on constantly or was pulsed;

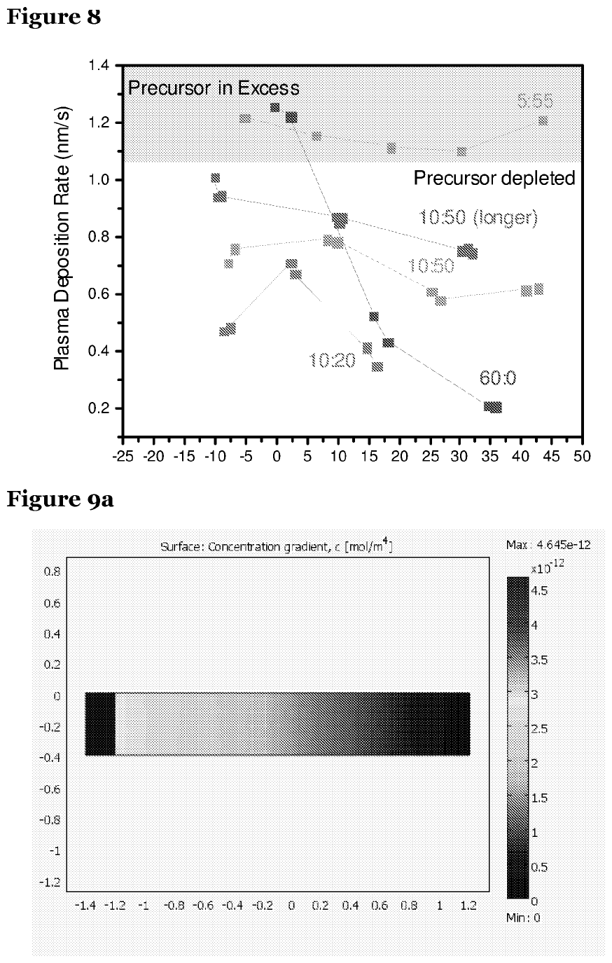

FIG. 8 is a graph showing the distance a component was placed from the input of the feedstock and the deposition rate of the deposited layers across the length of time the plasma was on when a power level of 200 W was used and the radio-frequency power supply was either on constantly or was pulsed; and

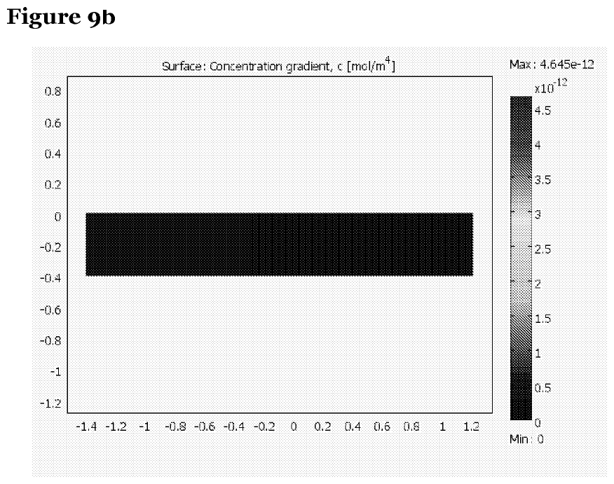

FIGS. 9a and 9b are graphs showing simulations of the concentration gradient of a poly(p-xylylene) monomer across a deposition chamber, the x and y axes distance in meters; FIG. 9a shows the initial conditions when the monomer is injected into the deposition chamber; and FIG. 9b shows the steady state conditions.

### EXAMPLE 1—POLY(P-XYLYLENE) POLYMER DEPOSITION APPARATUS

FIG. 1 is a simplified schematic diagram showing an apparatus 2 configured to deposit a film of poly(p-xylylene) polymer on an electrically conductive component 4. The apparatus comprises a deposition chamber 6 comprising a metallic housing 8. As shown in FIG. 1, the metallic housing 8 is earthed. The inside of the deposition chamber 6 may be accessed via a loading door 10, allowing the component 4 to be placed in the chamber 6 and subsequently removed therefrom.

When it is placed in the chamber 6, the component 4 may be disposed on a platen 12, which holds the component 4 above the base 14 of the deposition chamber 10 and electrically connects the component 4 to a radio-frequency electrical power supply 16. The radio-frequency power supply 16 used by the inventors operates at a frequency of 13.56 MHz, as this is an industrial, scientific and medical (ISM) radio band, and so will not disrupt radio communication. The component 4 is electrically insulated from the metallic housing 8 due to an insulating material 18 being disposed between the platen 12 and the housing 8.

The platen 12 may comprise a metallic rod 20 with a resilient metallic clip (not shown) disposed thereon. The metallic clip comprises spaced apart flanges joined by a connecting portion. A portion of the component 4 can slot between the flanges and the platen is thereby able to support the component 4. The metallic clip is sized so as to contact as little of the component 4 as possible, and typically contacts less than 1% of the surface of the component.

The apparatus 2 further comprises a delivery system 22, configured to deliver a vaporised monomer, such as a vaporised poly(p-xylylene) monomer, to the deposition chamber 6. For simplicity, elements of the delivery system 22 have been omitted from FIG. 1. A more complete representation of the delivery system 22 is provided in FIG. 2.

The delivery system 22 comprises a monomer reservoir 24 configured to receive a poly(p-xylylene) monomer therein. A monomer conduit 26 extends between the deposition chamber 6 and the monomer reservoir 24. A jacket heater 28 (only shown in FIG. 1) is disposed adjacent to the monomer reservoir 24 and a tracer heater 29 (again, only shown in FIG. 1) is disposed adjacent to the monomer conduit 26. The jacket heater 28 and trace heater 29 are controlled by a heating control unit 30. A liquid mass flow controller (MFC) 32 is disposed on the monomer conduit 26 and is controlled by a liquid MFC control unit 34. A first monomer valve 36 is disposed on the monomer conduit 26 between the MFC 32 and the monomer reservoir 24, and selectively isolates the monomer reservoir 24 from the rest of the delivery system 22. A second monomer valve 38 is disposed on the monomer conduit 26 between the MFC 32 and the deposition chamber 6, and selectively isolates the delivery system 22 from the deposition chamber 6.

The delivery system 22 further comprises a gas reservoir 40, configured to store a pure inert gas, such as nitrogen, therein. A gas conduit 42 extends between the gas reservoir and the monomer conduit 26, intersecting the monomer conduit 26 between the first monomer valve 36 and the MFC 32. A gas valve 44 is disposed on the gas conduit 42, and selectively isolates the gas reservoir 40 from the rest of the delivery system 22.

The delivery system 22 further comprises a connector 46 configured to be connected to a vacuum source and/or a helium leak tester. A connector conduit 48 extends between the connector 46 and the monomer conduit 26, and intersects the monomer conduit 26 between the first monomer valve 36 and the MFC 32. A connector valve 50 is disposed on the connector conduit 48.

The first and second monomer valves 36, 38, the gas valve 44 and the connector valve 50 are all solenoid valves and are connected to a control system (not shown). Connecting the connector conduit 48 to a helium leak tester allows a leak check to be conducted. Alternatively, connecting the connector conduit 48 to a vacuum source allows a pulse/purge regime to be carried.

The apparatus further comprises a turbo pump 52 and a pump conduit 54 extending between the turbo pump 52 and the deposition chamber 6. A pump valve 56 is disposed on the pump conduit 54. The pump valve 56 may be a gate valve or a throttle valve. The gate valve may be a manual gate valve or a pneumatic gate valve. The throttle valve may be an automatic pressure controller (APC) valve. An APC valve can automatically set its position in order to adjust a set pressure (ascertained from a pressure gauge in the main chamber) via electronics.

Finally, the apparatus 2 also comprises a gas source 58 and a further gas conduit 60 extending between the gas source 58 and the deposition chamber 6, with a valve 62 disposed thereon. This allows the selective injection of a gas into the deposition chamber 6.

To coat a component 4 with a film of poly(p-xylylene) polymer, a user first loads a poly(p-xylylene) monomer into the reservoir 24. The user also loads the component 4 into the deposition chamber 6, positing it on the platen 12.

The user can also place a small amount of an adhesion promotion agent, such as A-174, in the deposition chamber 10. The adhesion promotion agent can be provided in an open container, such as a petri dish. The amount of adhesion promotion agent required would depend upon the size of the component 4, but the inventors have typically used about 3 ml. It should be noted, that the use of a plasma, as described below, enhances the reactivity of the monomers and activates the surface of the component 4. Accordingly, the adhesion of the poly(p-xylylene) polymer is stronger than was possible previously. Accordingly, the adhesion agent may not be required. The user then closes the loading door 10, thereby hermetically sealing the deposition chamber 6, and ensures that the pump valve 56 is open and then activates the turbo pump 52 to cause the pressure within the deposition chamber 6 to reduce to lower than 10⁻³ Torr. This causes the adhesion agent, if present, to evaporate and coat the inside of the deposition chamber 6 and component 4.

The heating control unit 30 then activates the jacket heater 28 to heat the reservoir 24 to a temperature between 50 and 100° C. The heating control unit also activates the trace heater 29 to heat the monomer conduit 26 to a temperature of about 10° C. higher than the monomer reservoir 24. The temperature gradient ensures that the monomer does not condense in the monomer conduit 26.

If either of the monomer valves, 36, 38 are closed then they would be opened, either manually or automatically, prior to, at the same time or after activating the heaters 28, 29.

Heating of the reservoir causes the poly(p-xylylene) monomer to vaporise. The MFC controls the flow of the vaporised poly(p-xylylene) monomer from the reservoir 24, along the monomer conduit 26 and into the deposition chamber 6. The desired flow rate may depend on a variety of factors. The results discussed below were obtained using a flow rate of 2.5 sccm.

The user may turn-on the radio-frequency electrical power supply 16. The electrical power delivered by the radio-frequency electrical power supply 16 is typically 0.1 Watts/cm². Due to the metallic housing 8 of the deposition chamber 6 being grounded, it acts as a virtual electrode, and a plasma is created around the component 4. The plasma ionises and/or activates the monomers, typically causing them to become positively charged. The plasma activates the surface of the component 4. The ionised monomers are attracted to the component 4, deposit thereon and polymerise to form a poly(p-xylylene) polymer coating.

The radio-frequency electrical power supply 16 may be left on throughout the process. Alternatively, in some embodiments the radio-frequency electrical power supply 16 may supply power in a pulsed manner, as discussed in more detail below.

During deposition, additives can be added to the deposition chamber by injection from the gas source 58. These additives could include a hydrocarbon, such as acetylene, and/or an organometallic compound, such as tetraethyl orthosilicate (TEOS), and/or titanium isopropoxide (TIPP). The additives may be injected into the deposition chamber 10 throughout the deposition process so they are disposed throughout the coating to add functionality. Alternatively, they may be added at selected times to produce a multi-layer coating.

Once the desired coating thickness has been reached the user can stop the process. This can be achieved by deactivating the radio-frequency power supply 16, deactivating the pump 52 and closing the second monomer valve 38 and/or the MFC 32. The pump valve 56 may also be closed. The deposition chamber 6 can then be purged with air or nitrogen and brought up to atmospheric pressure. The user can then open the deposition chamber 10 and retrieve the coated component 4.

If a complete shutdown of the apparatus is required, the heaters 28, 29 can also be deactivated. Alternatively, the heaters 28, 29 may be left on. This ensures that the apparatus 2 is ready to coat another component more quickly that would otherwise be the case.

### EXAMPLE 2—LIQUID PRECURSOR DEPOSITION APPARATUS WITH A MODIFIED DELIVERY SYSTEM

In some embodiments the delivery system 22 may comprise multiple subunits. For instance, FIG. 3 shows a delivery system 22 comprising two subunits 64a, 64b. Each subunit 64a, 64b comprises a monomer reservoir 24a, 24b, a monomer conduit 26a, 26b, a liquid MFC 32a, 32b and first and second monomer valves 36a, 36b, 38a, 38b, as described in example 1.

The delivery system 22 comprises a primary gas conduit 66 which is configured to connect a gas source 40 with the subunits 64a, 64b. A primary gas valve 68 is disposed on the primary gas conduit 66, and is configured to isolate the gas source 40 from the reset of the delivery system. Each subunit 64a, 64b comprises a secondary gas conduit 42a, 42b which extends between the primary gas conduit 66 and the respective monomer conduits 26a, 26b, intersecting the respective monomer conduits 26a, 26b between the first monomer valve 36a, 36b and the MFC 32a, 32b. A secondary gas valve 44a, 44b is disposed on each secondary gas conduit 42a, 42b, and selectively isolates the respective subunit 64a, 64b from the gas reservoir 40.

The delivery system 22 further comprises a primary connector conduit 70 which is configured to connect the subunits 64a, 64b to a connector 46 configured to be connected to a vacuum source and/or a helium leak tester. A primary connector valve 72 is disposed on the primary connector conduit 70, and is configured to isolate the connector 46 from the reset of the delivery system. Each subunit 64a, 64b comprises a secondary connector conduit 48a, 48b which extends between the primary connector conduit 70 and the respective monomer conduits 26a, 26b, intersecting the respective monomer conduits 26a, 26b between the first monomer valve 36a, 36b and the MFC 32a, 32b. A secondary connector valve 50a, 50b is disposed on each secondary connector conduit 48a, 48b, and selectively isolates the respective subunit 64a, 64b from the connector 46.

While not shown in the Figure, it will be appreciated that the delivery system 22 shown in FIG. 3 would also comprise a heater 28 disposed adjacent to the monomer reservoirs 24a, 24b and the monomer conduits 26a, 26b, and is controlled by a heating control unit 30.

### EXAMPLE 3—LIQUID PRECURSOR DEPOSITION APPARATUS FOR USE WITH AN INSULATING COMPONENT

The apparatus 2 discussed in Examples 1 and 2 could be modified to deposit a layer from a liquid precursor on a component comprising an electrically insulating material. Such a component would be thin and substantially flat. The exact thickness of the component may vary. For instance, it is noted that the inventors have successfully used this method to coat components thicknesses between 2 and 3 cm. It will be appreciated that thicker components could be coated if a stronger electrical field were used.

The apparatus would be as described in Examples 1 and 2 except that the platen would define a flat platform configured to receive the component thereon. The apparatus would coat the exposed side of the component, and the component would then need to be repositioned to expose the other side thereof. The repositioning could be carried out manually by a user or automatically by equipment disposed within the deposition chamber.

### EXAMPLE 4—DEPOSITION OF MULTIPLE LAYERS ONTO A COMPONENT

The apparatus describes in Example 1 was used to deposit multiple layers, including a layer of a poly(p-xylylene) polymer, onto multiple components. The components were 1 cm×1 cm silicon witness samples. They were allocated through the entire length of the chamber. These components were used as they allow a thickness measurement of a deposited layer to be obtained. The experiment was conducted three different times with the power supplied to the component by the radio-frequency power supply varied each time. No carrier gas was used in these experiments.

The thickness of the multilayers on the components was measured as a function of the distance from the monomer input, and the results are shown in FIG. 4.

The advantages associated depositing a poly(p-xylylene) polymer layer onto a component using a liquid monomer feedstock are:

1. It is easy to set and maintained a flow rate of the monomer into the deposition chamber. This ensures that a steady deposition rate may be achieved.

2. It is possible to use multiple injection sites. This enables the deposition of a poly(p-xylylene) polymer layer onto components with more complex architecture than was previously possible.

3. A high temperature cracking step is not required. This significantly lowers the required temperature for deposition.

### EXAMPLE 5—DEPOSITION OF LIQUID PRECURSOR WHEN USING HYDROGEN CARRIER GAS

The apparatus describes in the Example 1 was used to deposit a layer from a liquid precursor on a component. The experimental details were as described in Example 4, except the power supplied to the component by the radio-frequency power supply was kept constant at 50 W and for five of the six experiments hydrogen was injected into the deposition chamber at a specific flow rate.

The results can be seen in FIGS. 5a and 5b. The results show that the most uniform deposition without plasma is associated with a carrier gas flow rate of 10 sccm. The linear approximations in 5b show that even with this improvement of uniformity, the maximum throwing distance is limited to at best about 1 m (i.e. the point where the line crosses the x axis).

One way to improve uniformity over greater distances would be to use multiple injection points for the monomer throughout the deposition chamber. Alternatively, or additionally, the plasma could be pulsed. This strategy was investigated by the inventors and is discussed below.

### EXAMPLE 6—INVESTIGATING THE EFFECT OF PLASMA PULSING

The apparatus described in the Example 1 was used to deposit a layer from a liquid precursor onto components. The components were as described in Example 4.

The power supplied to the component by the radio-frequency power supply was kept constant at 200 W. No carrier gas was used in these experiments. For the first experiment the plasma was maintained constantly for 10 minutes. For the following four experiments the plasma was pulsed on and off at regular intervals as indicated in table 1.

TABLE 1
Different deposition conditions used

| Symbol | | Length of | Length of time | Length of time |
|---|---|---|---|---|
| in | | deposition | with plasma on | with plasma off |
| FIGS. 6 | Pulsed | process/ | for each pulse/ | for each pulse/ |
| and 7 | plasma? | minutes | seconds | seconds |
| ▾ | No | 10 | — | — |
| ♦ | Yes | 20 | 10 | 20 |
| [symbol] | Yes | 10 | 10 | 50 |
| [symbol] | Yes | 20 | 10 | 50 |
| ● | Yes | 20 | 5 | 55 |

As can been seen from FIGS. 6 and 7, using the plasma in short bursts allowed the inventors to obtain a stable deposition rate across the chamber and very uniform coating. Extrapolating the results suggests that the use of 5:55 on:off pulse would only have a variation in deposition rate of about 0.5 nm/min up to a length of 5 m away from the input, see FIG. 7b.

FIG. 8 shows the deposition rate per second the plasma is on. Samples subjected to a pulsed plasma with a ratio of 5:55 on:off were found to have the same deposition rate across the chamber as a sample subjected to a constant plasma disposed directly under the inlet.

The inventors conducted a simulation of the precursor concentration gradient along the length of the chamber, and the results are shown in FIG. 9. In particular, FIG. 9a shows the monomer concentration across the deposition chamber. As can be seen in the Figure, the concentration of the monomer is highly variable across the chamber. This explains why a plasma which is applied constantly produces a non-uniform coating.

FIG. 9b shows the concentration gradient after the chamber has reached steady state. This shows that over time the monomer will spread throughout the deposition chamber, and the gradient is removed resulting in a uniform coating being obtained when a pulsed plasma is used.

1-24. (canceled)

25. An apparatus for depositing poly(p-xylylene) onto a component, the apparatus comprising:
a deposition chamber configured to receive a component to be coated therein;
an electrical power supply;
a platen, disposed inside the deposition chamber and comprising an electrically conductive material, wherein the platen is electrically connected to the electrical power supply and configured to support the component;
at least one monomer reservoir, configured to receive a monomer of poly(p-xylylene) therein;
a plurality of monomer conduits, each monomer conduit extending between the at least one monomer reservoir and the deposition chamber, and the plurality of monomer conduits being configured to inject the monomer into the deposition chamber at a plurality of locations; and
a heating means configured to heat the at least one monomer reservoir and the plurality of monomer conduits to a temperature of between 25 and 250° C.;
one or more monomer valves configured to selectively isolate the at least one monomer reservoir from the deposition chamber;
an electronic controller configured to control the electrical power supply and the one or more monomer valves, wherein the electronic controller is configured to finish a coating cycle by deactivating the electrical power supply prior to, at the same to as or after closing the, or each, monomer valve.

26. The apparatus of claim 25, wherein the plurality of monomer conduits extend between a single monomer reservoir and the deposition chamber or the plurality of monomer conduits extend between a plurality of monomer reservoirs and the deposition chamber.

27. The apparatus of claim 25, wherein the heating means comprises a first heater configured to heat the monomer reservoir and a second heater configured to heat the monomer conduit, optionally wherein the first heater comprises a jacket heater disposed adjacent to the monomer reservoir and the second heater comprises a trace heater disposed adjacent to the monomer conduit.

28. The apparatus of claim 27, wherein the heating means is configured to heat the monomer reservoir to a temperature of at least 30° C., more preferably at least 40° C. or at least 45° C., and most preferably at least 50° C.

29. The apparatus of claim 27, wherein the heating means is configured to heat the monomer conduit to a temperature at least 1° C., at least 2.5° C., at least 5° C., at least 7.5° C. or at least 9° C. higher than the temperature of the monomer reservoir.

30. The apparatus of claim 25, wherein the apparatus comprises a mass flow controller disposed on the monomer conduit and configured to control the flow rate of the monomer into the deposition chamber.

31. The apparatus of claim 25, wherein the electrical power supply is configured to supply electrical power to the platen in a pulsed manner from when it is activated to when it is deactivated.

32. The apparatus of claim 31 wherein each pulse comprises or consists of:
a) a first time period where electrical power is supplied to the platen, and
b) a second time period when electrical power is not supplied to the platen.

33. The apparatus of claim 31, wherein the ratio of the first time period to the second time period is between 1:1 and 1:1,000, between 1:1.5 and 1:500, between 1:2 and 1:100, between 1:3 and 1:50, between 1:4 and 1:20, between 1:5 and 1:20 or between 1:10 and 1:12.

34. The apparatus of claim 31, wherein each pulse has a duration between 1 second and 1 hour, between 10 seconds and 30 minutes, between 20 seconds and 10 minutes, between seconds and 5 minutes, between 40 seconds and 2 minutes or between 50 seconds and 90 seconds.

35. The apparatus of claim 25, wherein the apparatus further comprises a feedstock reservoir configured to store a feedstock therein and a feedstock conduit extending between the feedstock reservoir and the deposition chamber.

36. The apparatus of claim 35, wherein the feedstock reservoir is configured to store:
a feedstock configured to provide a diamond-like carbon (DLC) layer;
a feedstock configured to provide a layer comprising a metal or metalloid; and/or
a feedstock configured to provide an inorganic layer.

37. The apparatus of claim 25, wherein the electrical power supply is a direct current (DC) power supply or a radio-frequency electrical power supply.

38. The apparatus of claim 25, wherein the electrical power supply is configured to apply electrical power to the platen and/or the component at a power of between 0.0001 Watts/cm² and 10 Watts/cm², between 0.001 Watts/cm² and 5 Watts/cm², between 0.005 Watts/cm² and 1 Watts/cm² or between 0.01 and 0.5 Watts/cm².

39. The apparatus of claim 25, wherein the apparatus comprises an electrode, wherein the electrode is electrically insulated from the platen, optionally wherein the deposition chamber defines the electrode and is connected to electrical ground or earth.

40. The apparatus of claim 25, wherein the apparatus comprises a vacuum pump configured to reduce the pressure of the deposition chamber to a pressure of less than 10 Torr, less than 1 Torr, less than 0.1 Torr, less than 50 mTorr, less than 40 mTorr, less than 30 mTorr, less than 20 mTorr, less than 10 mTorr, less than 5 mTorr or less than 1 mTorr.

41. The apparatus of claim 25, wherein the apparatus comprises an injector, configured to inject an additive and/or a carrier gas into the deposition chamber.

42. A method of depositing a poly(p-xylylene) layer onto a component, the method not requiring a high temperature cracking step, and comprising:
supporting the component on a platen within a deposition chamber, wherein the platen comprises an electrically conductive material and is connected to an electrical power supply;
heating a monomer of poly(p-xylylene) to a temperature of between 25 and 250° C., and thereby causing it to vaporise, and feeding the monomer along a plurality of monomer conduits to inject the monomer into the deposition chamber at a plurality of locations, wherein the plurality of monomer conduits are heated to a temperature of between 25 and 250° C.;
activating the electrical power supply and thereby creating a plasma that surrounds the component and ionises and/or activates the monomer of poly(p-xylylene); and
allowing the ionised and/or activated monomer of poly(p-xylylene) to deposit on the component and polymerise, and thereby form poly(p-xylylene) on the component.

43. The method of claim 42, wherein the monomer is a compound of Formula (I): 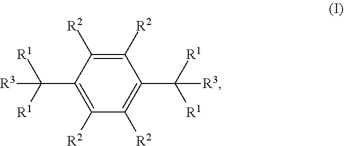
wherein each R¹ is independently H, a C₁₋₅ alkyl, a C₁₋₅ alkoxy, a polymer group chain or a halogen;
each R² is independently H, a C₁₋₅ alkyl, a halogen, CN or C(O)R⁴;
each R³ is OH or a C₁₋₅ alkoxy; and
R⁴ is H, a C₁₋₅ alkyl or a C₁₋₅ alkoxy.

44. The method of claim 42, wherein the method comprises causing the electrical power supply to provide electrical power to the platen in a pulsed manner.
